(19) United States
(12) Patent Application Publication
(10) Pub. No.: US 2025/0112161 A1
(43) Pub. Date: Apr. 3, 2025

(54) METHODS AND APPARATUS TO CONNECT INTERCONNECT BRIDGES TO PACKAGE SUBSTRATES

(71) Applicant: Intel Corporation, Santa Clara, CA (US)

(72) Inventors: Minglu Liu, Chandler, AZ (US); Seyyed Yahya Mousavi, Chandler, AZ (US); Yingying Zhang, Chandler, AZ (US); Gang Duan, Chandler, AZ (US); Andrey Gunawan, Paradise Valley, AZ (US); Yosuke Kanaoka, Chandler, AZ (US); Yiqun Bai, Chandler, AZ (US); Ziyin Lin, Chandler, AZ (US); Bohan Shan, Chandler, AZ (US); Dingying Xu, Chandler, AZ (US); Srinivas Pietambaram, Chandler, AZ (US); Hong Seung Yeon, Chandler, AZ (US)

(21) Appl. No.: 18/478,538

(22) Filed: Sep. 29, 2023

(51) Int. Cl. H01L 23/538; H01L 23/00; H01L 23/31

(52) U.S. Cl. CPC H01L 23/5381; H01L 23/3121; H01L 23/5383; H01L 23/5386; H01L 24/08; H01L 24/16; H01L 2224/08225; H01L 2224/16145; H01L 2224/16227

(57) ABSTRACT

Methods and apparatus to connect interconnect bridges to package substrates are disclosed. An example package substrate includes a dielectric layer including a cavity, a first contact pad positioned in the cavity, a first semiconductor die including a second contact pad and a third contact pad, the second contact pad positioned on a first surface of the first semiconductor die, the third contact pad positioned on a second surface of the first semiconductor die, the second surface opposite the first surface, the second contact pad coupled to the first contact pad, the third contact pad to be coupled to a second semiconductor die, and a non-conductive material surrounding the first contact pad and the second contact pad.

### FIELD OF THE DISCLOSURE

This disclosure relates generally to integrated circuit packages and, more particularly, to methods and apparatus to connect interconnect bridges to package substrates.

### BACKGROUND

In many integrated circuit packages, one or more semiconductor dies can be mechanically and electrically coupled to an underlying package substrate. In some instances, the underlying package substrate can include a semiconductor based interconnect bridge embedded therein.

### BRIEF DESCRIPTION OF THE DRAWINGS

FIG. 1 illustrates an example integrated circuit (IC) package on a printed circuit board (PCB).

FIG. 2 is a cross-sectional view of an example package substrate that may be included in the example IC package of FIG. 1.

FIG. 3 is a flowchart representative of an example method to manufacture an example package substrate disclosed herein.

FIGS. 4A-4D illustrate different stages in an example process of manufacturing the example package substrate of FIG. 2.

FIGS. 5A-5C illustrate different stages in an example process of manufacturing another example package constructed in accordance with teachings disclosed herein.

FIGS. 6A-6C illustrate different stages in an example process of manufacturing another example package constructed in accordance with teachings disclosed herein.

FIG. 7 is a top view of a wafer including dies that may be included in an IC package constructed in accordance with teachings disclosed herein.

FIG. 8 is a cross-sectional side view of an IC device that may be included in an IC package constructed in accordance with teachings disclosed herein.

FIG. 9 is a cross-sectional side view of an IC device assembly that may include an IC package constructed in accordance with teachings disclosed herein.

FIG. 10 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs).

For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

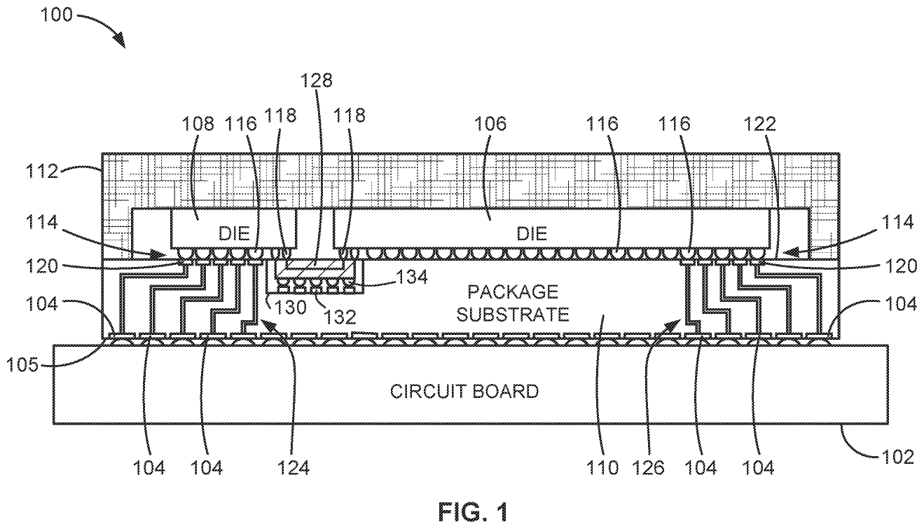

FIG. 1 illustrates an example IC package (e.g., a semiconductor package) 100 constructed in accordance with teachings disclosed herein. In the illustrated example, the IC package 100 is conductively (e.g., electrically) coupled to an example circuit board 102 via an array of example contact pads or lands 104 on an example mounting surface (e.g., a bottom surface) 105 of the package. In some examples, the IC package 100 may include balls, pins, and/or pads, in addition to or instead of the contact pads 104, to enable the conductive coupling of the package 100 to the circuit board 102. In this example, the package 100 includes two example semiconductor (e.g., silicon) dies 106, 108 (sometimes also referred to as chips or chiplets) that are mounted to an example package substrate 110 and enclosed by an example package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is conductively and mechanically coupled to the substrate 110 via corresponding arrays of example interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and conductively coupled to contact pads 120 on an example inner surface 122 of the substrate 110. The contact pads 120 on the inner surface 122 of the package substrate 110 are conductively coupled to the landing pads 104 on the bottom (external) surface 105 of the substrate 110 (e.g., a surface opposite the inner surface 122) via example internal interconnects 124, 126 within the substrate 110. As a result, there is a complete signal path between the bumps 116 of the dies 106, 108 and the landing pads 104 mounted to the circuit board 102 that pass through the contact pads 120 and the interconnects 124, 126 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., an example interconnect bridge 128 of FIG. 1) embedded in an underlying substrate (e.g., the package substrate 110). In some examples, the interconnect bridge 128 is fabricated from a semiconductor wafer in a manner similar to the dies 106, 108. Thus, the interconnect bridge 128 is also sometimes referred to herein as a semiconductor die or a semiconductor based interconnect bridge. As represented in FIG. 1, core bumps 116 are typically larger than bridge bumps 118. In this example, the interconnect bridge 128 is positioned within an example cavity 130 in the inner surface 122 of the package substrate 110. In the past, interconnect bridges typically included contacts pads on the surface facing away from the package substrate 110 and toward the dies 106, 108 (e.g., to provide conductive coupling between the dies 106, 108). However, in this example, the example interconnect bridge 128 is conductively and mechanically coupled to the package substrate 110 via first example contact pads 132 (on the package substrate 110) and second example contact pads 134 (on the interconnect bridge 128). Therefore, the dies 106, 108 may be conductively coupled to one another and to the package substrate 110 via the bridge bumps 118, the interconnect bridge 128, and the contact pads 132, 134.

In some examples, mechanically coupling (e.g., embedding) the interconnect bridge 128 to the package substrate 110 is accomplished by soldering the first and second contact pads 132, 134 such that electrical signals can pass between the interconnect bridge 128 and the package substrate 110. In particular, the second contact pads 134 on the interconnect bridge 128 are soldered to the first contact pads 132 on the package substrate 110. In such examples, the package substrate 110 includes additional internal interconnects 124, 126 conductively coupled to the first contact pads 132 to provide a signal path through the package substrate 110. In some examples, mechanically coupling the interconnect bridge 128 to the package substrate 110 may utilize mass reflow techniques (e.g., thermocompression bonding) to heat and compress the solder connections corresponding to the first and second contact pads 132, 134. However, these mass reflow techniques can produce residual material (e.g., solder material, flux residue, etc.) in the regions adjacent to the first and second contact pads 132, 134. For example, a first one of the first contact pads 132 can be coupled to a second one of the second contact pads 134 using mass reflow techniques, but residual material can extend into a region surrounding the coupled first and second ones of the contact pads 132, 134. In some examples, residual material between the interconnect bridge 128 and the package substrate 110 can prevent the flow or adhesion of underfill materials. As a result, delaminated underfill materials may not be able to provide a sufficient bond between the interconnect bridge 128 and the package substrate 110. In densely packed package substrates, residual material can have adverse effects on the electrical performance of the corresponding IC package. For example, residual solder material can short circuit electrical connections between interconnects (e.g., between adjacent pairs of the contact pads 132, 134) by diverting the electrical signals through the corresponding interconnect. In other examples, residual solder material can absorb ambient moisture which, in turn, can corrode and damage adjacent components of the IC package.

Potential solutions to remove the residual material include deflux techniques to insert (e.g., flow) water between the solder connections to clean or remove any residual material. In some examples, deflux techniques can use high pressure water and/or high temperature water to attempt to remove residual material. However, as IC packages become more and more densely packed, cleaning tools may not be able to access solder connections between components, solder connections within cavities, etc. Further, some residual materials may not be water soluble and, thus, may not be removed by deflux techniques that include water. As such, conventional deflux techniques can still leave residual material.

Examples disclosed herein utilize a non-conductive material to cover (e.g., protect, encapsulate, etc.) interconnects (e.g., the contact pads 132, 134) between semiconductor based interconnect bridges and package substrates. Examples disclosed herein dispose a non-conductive material onto interconnects prior to mass reflow techniques that thermally bond an example interconnect bridge to an example package substrate. In disclosed examples, the non-conductive material inhibits residual material from spreading or leaking into adjacent regions in response to mass reflow techniques. As such, disclosed examples enable sufficient mechanical and electrical coupling between interconnect bridges and package substrates. In particular, disclosed examples enclose coupled contact pads between an example interconnect bridge and a package substrate to guard against residue leakage. Further, examples disclosed herein can bypass previous, conventional deflux techniques to remove such residual material.

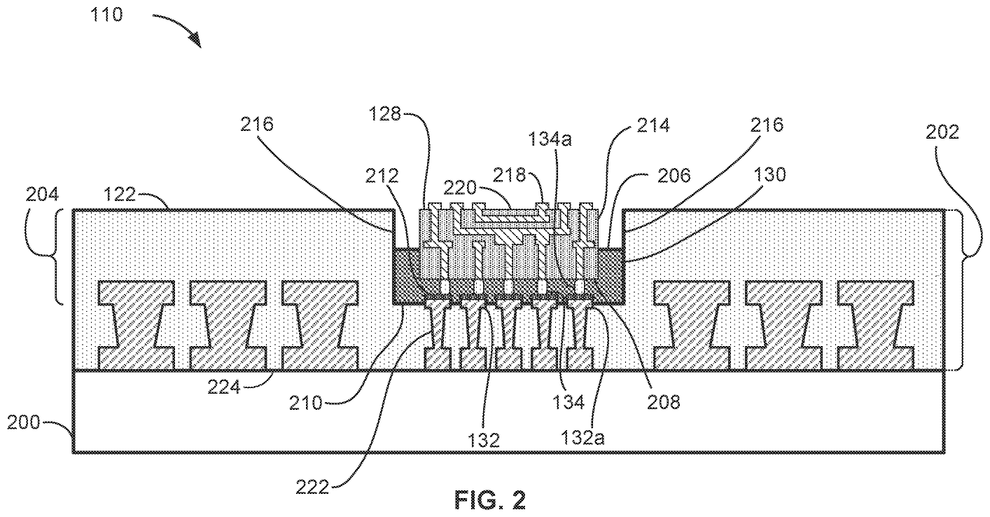

FIG. 2 illustrates a cross-sectional view of a portion of the example package substrate 110 of FIG. 1. Specifically, the portion of the package substrate 110 shown in FIG. 2 corresponds to layers of the package substrate 110 from an example core (e.g., glass core, organic core, etc.) 200 of the package substrate 110 to the inner surface 122 of the package substrate 110. The portion of the example package substrate 110 shown in FIG. 2 includes the interconnect bridge 128, an example build-up region 202 including an example dielectric layer 204, and an example non-conductive material (e.g., non-conductive coating, non-conductive paste, epoxy flux material, non-conductive adhesive, etc.) 206. The example build-up region 202 is adjacent to the interconnect bridge 128. Further, the example dielectric layer 204 includes the cavity 130. Although the dielectric layer 204 is represented in FIG. 2 as a single, unitary layer of material, in some examples, the dielectric layer 204 may include multiple layers of laminated dielectric material. In some such examples, the package substrate 110 may include one or more conductive layers between adjacent ones of the dielectric layers. As discussed above, in some examples, the interconnect bridge 128 constitutes and/or can be implemented as an example semiconductor die (e.g., similar to the die 106, the die 108, etc.). However, in some examples, the semiconductor die that serves as the interconnect bridge 128 does not include any active semiconductor devices (e.g., does not include transistors). In other examples, the semiconductor die that serves as the interconnect bridge 128 includes active semiconductor devices.

In the illustrated example of FIG. 2, the example interconnect bridge 128 is electrically and mechanically coupled to the package substrate 110. In particular, the first contact pads 132 positioned in the cavity 130 are coupled to the second contact pads 134 positioned on the interconnect bridge 128. The second example contact pads 134 are positioned on a first example surface 208 of the interconnect bridge 128. Further, the first contact pads 132 are positioned on a second example surface 210 of the package substrate 110. In some examples, the package substrate 110 is mechanically coupled (e.g., attached) to the interconnect bridge 128 via a solder joint connection. In this example, the first contact pads 132 include an example surface finish 212 (e.g., gold (Au) surface finish) to promote solder formation between the first contact pads 132 and the second contact pads 134.

The example interconnect bridge 128 is supported on the second surface 210. In FIG. 2, the first example surface 208 faces the second surface 210. Further, the second example surface 210 is recessed relative to the inner surface 122 of the package substrate 110 (defining the cavity 130). In this example, the inner surface 122 (as well as the recessed second surface 210) is facing in a first direction and the first surface 208 is facing in a second direction opposite the first direction.

The example non-conductive material 206 is between the first surface 208 of the interconnect bridge 128 and the second surface 210 of the package substrate 110. In some examples, the non-conductive material 206 surrounds the first contact pads 132 and the second contact pads 134. In some examples, the non-conductive material 206 can enclose ones of the first and second contact pads 132, 134 that are conductively coupled. For example, a first one of the first contact pads 132 (e.g., the contact pad 132a) is conductively coupled to a first one of the second contact pads 134 (e.g., the contact pad 134a). Further, the contact pad 132a is in contact (e.g., mechanical contact) with the contact pad 134a. As such, the contact pad 132a and the contact pad 134a can define a first pair of the coupled ones of the first contact pads 132 and the second contact pads 134. The example non-conductive material 206 can enclose (e.g., surround, coat, encapsulate, etc.) the first pair and any other pairs of the first contact pads 132 and the second contact pads 134. For example, the non-conductive material 206 can be between (e.g., to electrically isolate) corresponding pairs of the first and second contact pads 132, 134. In the illustrated example of FIG. 2, the cross-sectional view emphasizes the mechanical connections between the pairs of the first contact pads 132 and the second contact pads 134. However, the non-conductive material 206 can cover (e.g., fully cover) each of the pairs of the first and second contact pads 132, 134.

The example non-conductive material 206 can be between a third example surface 214 (e.g., a lateral surface, an edge surface, etc.) of the interconnect bridge 128 and the second surface 210 of the package substrate 110. For example, the non-conductive material 206 can fill a space between example walls 216 of the cavity 130 and the interconnect bridge 128. Accordingly, the interconnect bridge 128 is spaced apart from the walls 216 of the cavity 130 such that the non-conductive material 206 can at least partially cover the second surface 210 of the package substrate 110. Further, the non-conductive material 206 can at least partially cover the third surface 214 of the interconnect bridge 128. In some examples, the interconnect bridge 128 may be spaced 40 micrometer (μm) or less, 50 μm or less, 60 μm or less, etc., from the walls 216 of the cavity 130.

In some examples, the interconnect bridge 128 is couplable to additional semiconductor dies (e.g., the die 106, the die 108, etc.). For example, at least one of third example contact pads 218 positioned on a fourth example surface 220 of the interconnect bridge 128 can be coupled to the die 106 and/or the die 108. In this example, the fourth surface 220 (e.g., the die-side surface) is opposite the first surface 208 (e.g., the package substrate side surface). Further, a first one of the third contact pads 218 can couple to the die 106 and a second one of the third contact pads 218 can couple to the die 108. Accordingly, the die 106 can be conductively coupled to the die 108 through the third contact pads 218. In some examples, the dies 106, 108 can include contact pads that can conductively couple to the third contact pads 218. For example, the bridge bumps 118 can conductively couple to the third contact pads 218 to facilitate electrical connection between the dies 106, 108 and the interconnect bridge 128. Thus, the example interconnect bridge 128 can be implemented as an embedded multi-die interconnect bridge (EMIB).

Further, the example interconnect bridge 128 can conductively couple to example vias 222. As shown in FIG. 2, the example vias 222 extend through the build-up region 202. In particular, the example vias 222 extend from the first contact pads 132 towards a fifth example surface 224 of the build-up region 202, the fifth example surface facing away from the second surface 210. In some examples, the vias 222 serve as and/or corresponding to ones of the internal interconnects 124, 126 that extend through the package substrate 110 as shown in FIG. 1. The example vias 222 and the interconnect bridge 128 are conductively coupled through the first and second contact pads 132, 134. In some examples, the vias 222 are referred to as through silicon vias (TSVs). Thus, the interconnect bridge 128 can be implemented as a TSV-EMIB (EMIB-T).

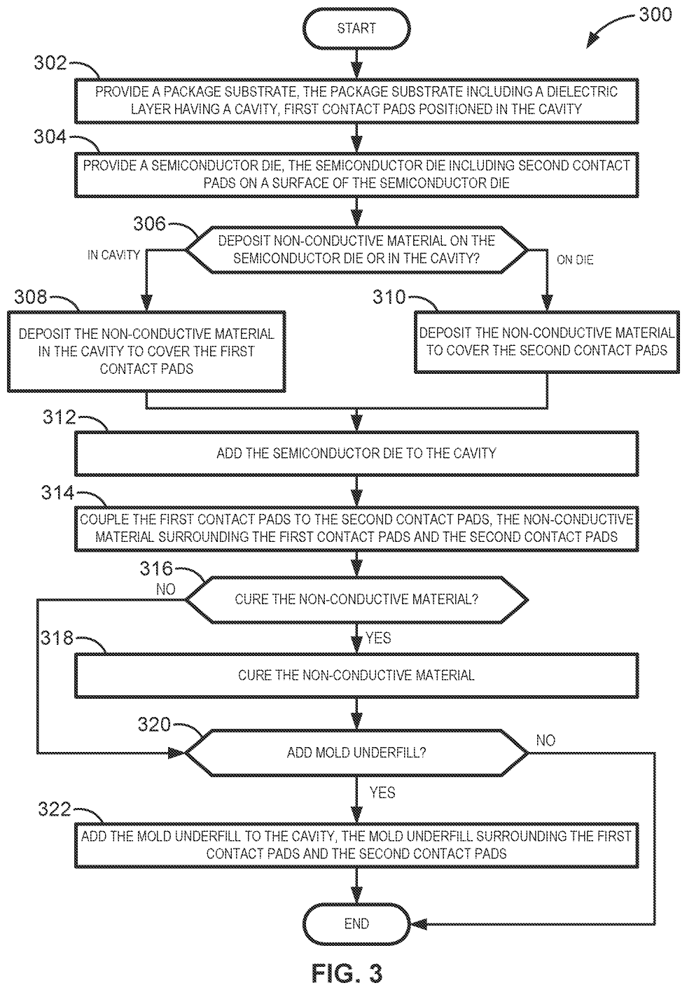

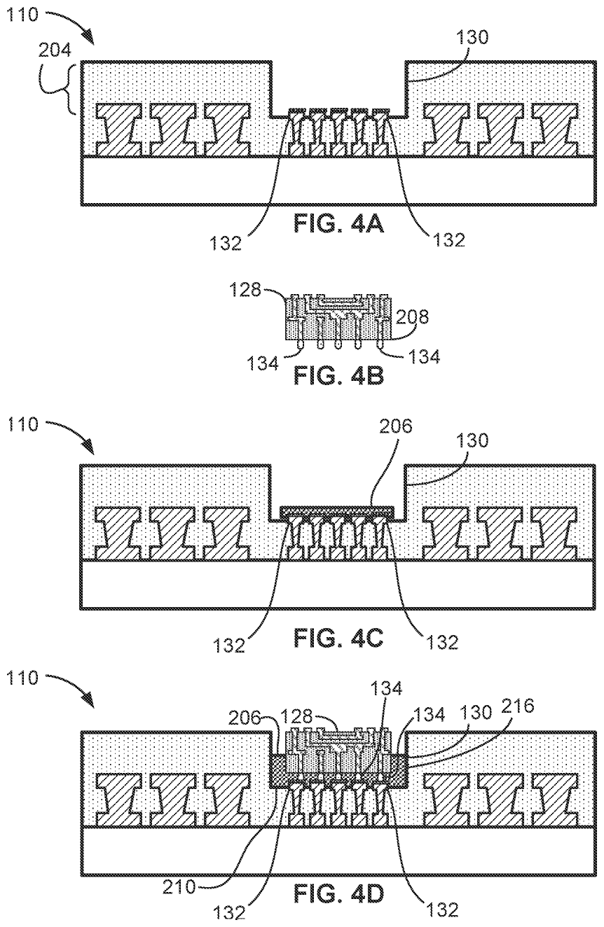

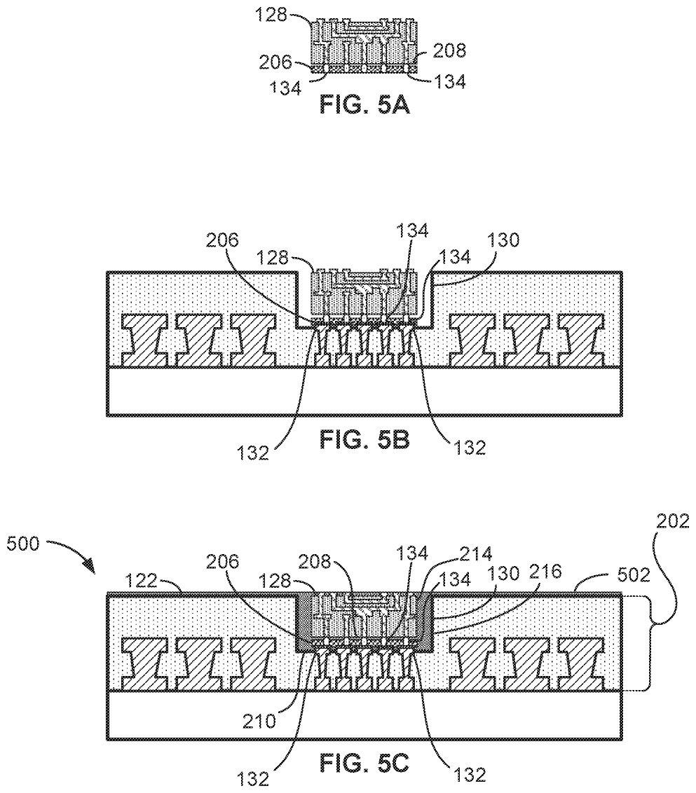

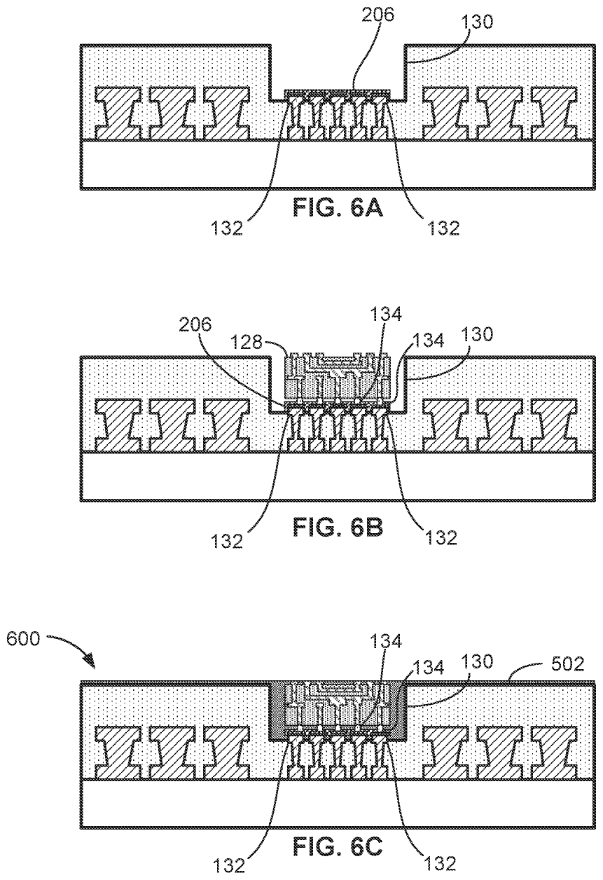

FIG. 3 is a flowchart representative of an example method 300 to produce the example package substrate 110 of FIG. 2, an example package substrate 500 of FIG. 5C, and an example package substrate 600 of FIG. 6C. FIGS. 4A and 4B represent a common starting point for each of the example package substrates 110, 500, 600 of FIGS. 2, 5C, and 6C. Thus, FIGS. 4A-4D represent the example package substrate 110 of FIG. 2 at various stages during the example process described in FIG. 3; FIGS. 4A, 4B, and 5A-5C represent the example package substrate 500 at various stages during the example process described in FIG. 3; and FIGS. 4A, 4B and 6A-6C represent the example package substrate 600 at various stages during the example process described in FIG. 3. In some examples, some or all of the operations outlined in the example method of FIG. 3 are performed automatically by fabrication equipment that is programmed to perform the operations. Although the example method of manufacture is described with reference to the flowchart illustrated in FIG. 3, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 3, the example process begins at block 302 at which an example package substrate is provided, the package substrate including an example dielectric layer having an example cavity, first example contact pads positioned in the cavity. As shown in FIG. 4A, the example package substrate 110 is provided. The example package substrate 110 includes the dielectric layer 204 having the cavity 130. Further, the first example contact pads 132 are positioned in the cavity 130.

At block 304, an example semiconductor die is provided, the semiconductor die including second contact pads on an example surface of the semiconductor die. As shown in FIG. 4B, the example interconnect bridge 128 (e.g., a semiconductor die) is provided. The example interconnect bridge 128 includes the second contact pads 134 on the first surface 208 of the interconnect bridge 128.

At block 306, it is determined whether example non-conductive material is to be deposited on the example semiconductor die (e.g., interconnect bridge) or in the example cavity. If the example non-conductive material is to be deposited in the cavity, the process proceeds to block 308. Alternatively, if the example non-conductive material is to be deposited on the semiconductor die, then the process proceeds to block 310. In some examples, both block 308 and block 310 may be implemented. In the example process illustrated by FIGS. 4A-4D, the process proceeds to block 308.

At block 308, example non-conductive material is deposited in the cavity to cover the first contact pads. As shown in FIG. 4C, the non-conductive material 206 is deposited (e.g., added, dispensed, printed, etc.) in the cavity 130 to cover the first contact pads 132.

At block 312, the example semiconductor die is added to the cavity. As shown in FIG. 4D, the example interconnect bridge 128 is added to the cavity 130.

At block 314, the first example contact pads are coupled to the second example contact pads, the non-conductive material surrounding the first contact pads and the second contact pads. As shown in FIG. 4D, the first example contact pads 132 are coupled to the second contact pads 134. In some examples, the first contact pads 132 are coupled to the second contact pads 134 via mass reflow techniques, thermocompression bonding, etc. Further, the example non-conductive material 206 is surrounding (e.g., covering, enclosing, etc.) the first contact pads 132 and the second contact pads 134. For example, the non-conductive material 206 can surround the coupled pairs of the first contact pads 132 and the second contact pads 134. In some examples, the non-conductive material 206 can be implemented as an example underfill material (e.g., between the interconnect bridge 128 and the package substrate 110). In some examples, the non-conductive material 206 is a non-conductive paste (e.g., Henkel non-conductive paste (NCP) 5209).

In some examples, the non-conductive material 206 is sandwiched between the interconnect bridge 128 and the package substrate 110. For example, the non-conductive material 206 can cover the first and second contacts pads 132, 134 and protrude laterally away from the first and second contact pads 132, 134 towards the walls 216 of the cavity 130. In some examples, the portion of the non-conductive material 206 protruding away from the first and second contact pads 132, 134 includes a generally circular (e.g., semicircular) shape and/or any other shape that defines an overhang over the underlying surface (e.g., the second surface 210) of the package substrate 110. That is, in some such examples, the point of the non-conductive material 206 that protrudes the farthest from the first and second contact pads 132, 134 and towards the walls 216 is spaced apart from the second surface 210. In other examples, the portion of the non-conductive material 206 protruding away from the first and second contact pads 132, 134 can form a fillet between the interconnect bridge 128 and the package substrate 110. That is, in some such examples, the point of the non-conductive material 206 that protrudes the farthest from the first and second contact pads 132, 134 is directly adjacent to the second surface 210.

At block 316, it is determined whether to cure the example non-conductive material. If it is determined to cure the example non-conductive material, the process proceeds to block 318. If it is determined to not cure the example non-conductive material, the process proceeds to block 320. Curing of the non-conductive material is suitable when the non-conductive material is an epoxy as discussed further below in connection with FIGS. 5A-5C and FIGS. 6A-6C. In the example process illustrated by FIGS. 4A-4D, the process proceeds to block 320.

At block 320, it is determined whether to add example mold underfill. If it is determined to add the example mold underfill, the process proceeds to block 322. If it is determined to not add the example mold underfill, the process proceeds ends. As noted above, the non-conductive material added in connection with the process represented by FIGS. 4A-4D serves as an underfill material such that there is no need for an additional mold underfill. Accordingly, in the example process illustrated by FIGS. 4A-4D, the process ends.

Returning to block 306, if it is determined that the example non-conductive material is to be deposited on the semiconductor die, the process proceeds to block 310 with the subsequent stages of fabrication represented by FIGS. 5A-5C. At block 310, the example non-conductive material is deposited on the semiconductor die to cover the second contact pads. As shown in FIG. 5A, the example non-conductive material 206 is deposited on the interconnect bridge 128 to at least partially cover (e.g., cover, completely cover, etc.) the second contact pads 134. In some examples, the interconnect bridge 128 is partially dipped in a pool of the non-conductive material 206 to deposit the non-conductive material 206 on the interconnect bridge 128. For example, the first surface 208 of the interconnect bridge 128 may face in a direction towards an example pool of the non-conductive material 206. Accordingly, the first surface 208 including the second contact pads 134 may be dipped in the non-conductive material 206. In some examples, the non-conductive material 206 is an example epoxy flux material. In some examples, the epoxy flux material is Macdermid Alpha, NCX009.

At block 312, the example semiconductor die is added to the cavity. In some examples, the implementation of block 312 in connection with FIG. 5B is similar or identical to the implementation of block 312 described above in connection with FIG. 4D. As shown in FIG. 5B, the interconnect bridge 128 is added to the cavity 130.

At block 314, the first example contact pads are coupled to the second example contact pads, the non-conductive material surrounding the first contact pads and the second contact pads. In some examples, the implementation of block 314 in connection with FIG. 5B is similar or identical to the implementation of block 314 described above in connection with FIG. 4D. As shown in FIG. 5B, the first contact pads 132 are coupled to the second contact pads 134. In some examples, the first contact pads 132 are coupled to the second contact pads 134 via mass reflow techniques, thermocompression bonding, etc. Further, the example non-conductive material 206 surrounds the coupled ones of the first and second contact pads 132, 134.

Returning to block 316, if it is determined that the example non-conductive material is to be cured, the process proceeds to block 318 with the subsequent stages of fabrication represented by FIGS. 5B-5C. As noted above, the non-conductive material added in connection with the process represented by FIGS. 5A-5C is an epoxy flux material that is to be cured. Accordingly, in such examples, the process advances to block 318 where the example non-conductive material 206 is cured.

Returning to block 320, if it is determined to add the example mold underfill, the process proceeds to block 322 with the subsequent stages of fabrication represented by FIG. 5C. At block 322, the example mold underfill is added to the cavity to surround the first contact pads and the second contact pads. As shown in FIG. 5C, example mold underfill (e.g., mold material, underfill material, etc.) 502 is added in the cavity 130. Further, the example mold underfill 502 surrounds the first contact pads 132 and the second contact pads 134. In some examples, the mold underfill 502 surrounds the non-conductive material 206. However, the mold underfill 502 can mix (e.g., merge) with the non-conductive material 206. In some examples, the mold underfill 502 surrounds the interconnect bridge 128. In the illustrated example of FIG. 5, the mold underfill 502 is between the interconnect bridge 128 and the second surface 210 of the package substrate 110. Further, the example mold underfill 502 can contact the interconnect bridge 128 and the second surface 210 of the package substrate 110. In FIG. 5C, the example mold underfill 502 covers the first surface 208 of the interconnect bridge 128 and the third surface 214 of the interconnect bridge 128. Put differently, the example mold underfill 502 can be between the interconnect bridge 128 and the wall(s) 216 of the cavity 130. In some examples, the mold underfill 502 covers the inner surface 122 of the package substrate 110 (and the build-up region 202). In some examples, Fourier-transform infrared spectroscopy can identify (e.g., distinguish, detect, etc.) the mold underfill 502 and the non-conductive material 206. Then, the process ends.

Returning to block 306, if it is determined that the example non-conductive material is to be deposited in the cavity, the process proceeds to block 308 with the subsequent stages of fabrication represented by FIGS. 6A-6C. At block 308, the example non-conductive material is deposited in the cavity to cover the first contact pads. As shown in FIG. 6A, the example non-conductive material 206 is deposited in the cavity 130 to cover the first contact pads 132. The stage of fabrication represented by FIG. 6A is distinct from the stage of fabrication represented in FIG. 4C discussed above due to a difference in the material used for the non-conductive material 206. Whereas the non-conductive material 206 used in FIG. 4C is a non-conductive paste, the non-conductive material 206 used in FIG. 6A is an epoxy flux material (similar to the epoxy flux material discussed above in connection with FIGS. 5A-5C).

At block 312, the example semiconductor die is added to the cavity. In some examples, the implementation of block 312 in connection with FIG. 6B is similar or identical to the implementation of block 312 described above in connection with FIG. 4D. As shown in FIG. 6B, the example interconnect bridge 128 is added to the cavity 130.

At block 314, the first example contact pads are coupled to the second contact pads, and the non-conductive material is to surround the first contact pads and the second contact pads. In some examples, the implementation of block 314 in connection with FIG. 6B is similar or identical to the implementation of block 314 described above in connection with FIG. 4D. As shown in FIG. 6B, the first example contact pads 132 are coupled to the second contact pads 134. Alternatively, the second contact pads 134 are coupled to the first contact pads 132. In some examples, the first contact pads 132 are coupled to the second contact pads 134 via mass reflow techniques, thermocompression bonding, etc. Further, the example non-conductive material 206 at least partially surrounds the first contact pads 132 and the second contact pads 134.

Returning to block 316, if it is determined that the example non-conductive material is to be cured, the process proceeds to block 318 with the subsequent stages of fabrication represented by FIGS. 6B-6C. As noted above, the non-conductive material added in connection with the process represented by FIGS. 6A-6C is an epoxy flux material that is to be cured. Accordingly, in such examples, the process advances to block 318 where the example non-conductive material is cured. As shown in FIG. 6B, the example non-conductive material 206 is cured.

Returning to block 320, if it is determined that the example mold underfill is to be added, then the process proceeds to block 322 with the subsequent stages of fabrication represented by FIG. 6C. At block 322, the example mold underfill is added to the cavity to surround the first contact pads and the second contact pads. In some examples, the implementation of block 322 in connection with FIG. 6C is similar or identical to the implementation of block 322 described above in connection with FIG. 5C. As shown in FIG. 6C, the example mold underfill 502 is added in the cavity 130. The example mold underfill 502 surrounds the first contact pads 132 and the second contact pads 134. Then, the process ends.

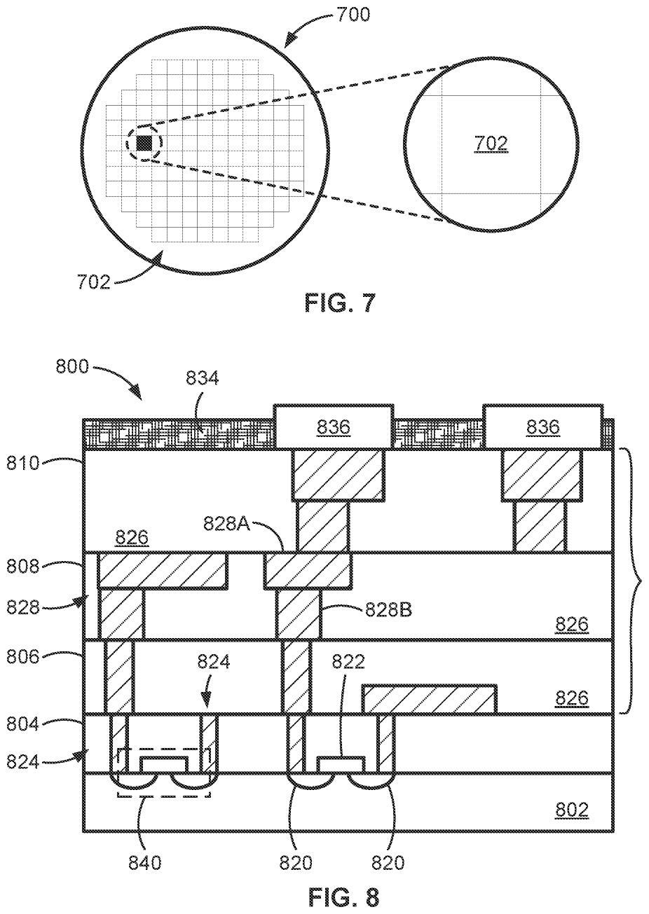

The example package substrates 110, 500, 600 disclosed herein may be included in any suitable electronic component. FIGS. 7-10 illustrate various examples of apparatus that may include or be included in the IC packages substrates 110, 500, 600 disclosed herein.

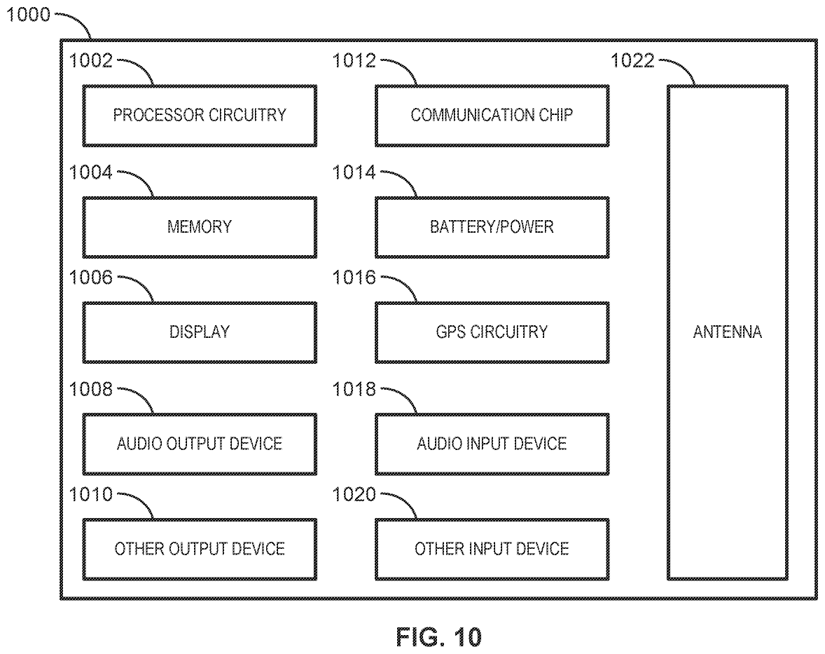

FIG. 7 is a top view of an example wafer 700 and dies 702 that may be included in the IC package 100 (e.g., as any suitable ones of the dies 106, 108 and/or the interconnect bridge 128). The wafer 700 may be composed of semiconductor material and may include one or more dies 702 having circuitry. Some or all of the dies 702 may be a repeating unit of a semiconductor product. After the fabrication of the semiconductor product is complete, the wafer 700 may undergo a singulation process in which the dies 702 are separated from one another to provide discrete “chips.” The die 702 may include one or more transistors (e.g., some of the transistors 840 of FIG. 8, discussed below), supporting circuitry to route electrical signals to the transistors, passive components (e.g., traces, resistors, capacitors, inductors, and/or other circuitry), and/or any other components. In some examples, the die 702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 702. For example, a memory array formed by multiple memory circuits may be formed on a same die 702 as programmable circuitry (e.g., the processor circuitry 1002 of FIG. 10) or other logic circuitry. Such memory may store information for use by the programmable circuitry. The example IC package 100 disclosed herein may be manufactured using a die-to-wafer assembly technique in which some dies 106, 108 and/or the interconnect bridge 128 are attached to a wafer 700 that include others of the dies 106, 108 and/or the interconnect bridge 128, and the wafer 700 is subsequently singulated.

FIG. 8 is a cross-sectional side view of an example IC device 800 that may be included in the example IC package 100 (e.g., in any one of the dies 106, 108 and/or the interconnect bridge 128). One or more of the IC devices 800 may be included in one or more dies 702 (FIG. 7). The IC device 800 may be formed on an example die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some examples, the die substrate 802 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an IC device 800 may be used. The die substrate 802 may be part of a singulated die (e.g., the dies 702 of FIG. 7) or a wafer (e.g., the wafer 700 of FIG. 7).

The IC device 800 may include one or more example device layers 804 disposed on or above the die substrate 802. The device layer 804 may include features of one or more example transistors 840 (e.g., metal oxide semiconductor field-effect transistors (MOSFETs)) formed on the die substrate 802. The device layer 804 may include, for example, one or more example source and/or drain (S/D) regions 820, an example gate 822 to control current flow between the S/D regions 820, and one or more example S/D contacts 824 to route electrical signals to/from the S/D regions 820. The transistors 840 may include additional features not depicted for the sake of clarity such as, for example, device isolation regions, gate contacts, and the like. The transistors 840 are not limited to the type and configuration depicted in FIG. 8 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 840 may include an example gate 822 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as, for example, a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 840 along the source-channel-drain direction, the gate electrode may include a U-shaped structure that includes a bottom portion substantially parallel to the surface of the die substrate 802 and two sidewall portions that are substantially perpendicular to the top surface of the die substrate 802. In other examples, at least one of the metal layers that form the gate electrode may be a planar layer that is substantially parallel to the top surface of the die substrate 802 and does not include sidewall portions substantially perpendicular to the top surface of the die substrate 802. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of respective ones of the transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes the dopants to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 820 may be formed using one or more alternate semiconductor materials such as germanium or a group III-V material or alloy. In further examples, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more example interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with example interconnect structures 828 of the interconnect layers 806-810. The one or more interconnect layers 806-810 may form an example metallization stack (also referred to as an “ILD stack”) 819 of the IC device 800.

The interconnect structures 828 may be arranged within the interconnect layers 806-810 to route electrical signals according to a wide variety of designs (in particular, the arrangement is not limited to the particular configuration of interconnect structures 828 depicted in FIG. 8). Although a particular number of interconnect layers 806-810 is depicted in FIG. 8, examples of the present disclosure include IC devices having more or fewer interconnect layers than depicted.

In some examples, the interconnect structures 828 may include example lines 828a and/or example vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page from the perspective of FIG. 8. The vias 828b may be arranged to route electrical signals in a direction of a plane that is substantially perpendicular to the surface of the die substrate 802 upon which the device layer 804 is formed. In some examples, the vias 828b may electrically couple lines 828a of different interconnect layers 806-810 together.

The interconnect layers 806-810 may include an example dielectric material 826 disposed between the interconnect structures 828, as shown in FIG. 8. In some examples, the dielectric material 826 disposed between the interconnect structures 828 in different ones of the interconnect layers 806-810 may have different compositions. In other examples, the composition of the dielectric material 826 between different interconnect layers 806-810 may be the same.

A first interconnect layer 806 (referred to as Metal 1 or “M1”) may be formed directly on the device layer 804. In some examples, the first interconnect layer 806 may include lines 828a and/or vias 828b, as shown. The lines 828a of the first interconnect layer 806 may be coupled with contacts (e.g., the S/D contacts 824) of the device layer 804.

A second interconnect layer 808 (referred to as Metal 2 or “M2”) may be formed directly on the first interconnect layer 806. In some examples, the second interconnect layer 808 may include vias 828b to couple the lines 828a of the second interconnect layer 808 with the lines 828a of the first interconnect layer 806. Although the lines 828a and the vias 828b are structurally delineated with a line within each interconnect layer (e.g., within the second interconnect layer 808) for the sake of clarity, the lines 828a and the vias 828b may be structurally and/or materially contiguous (e.g., simultaneously filled during a dual-damascene process) in some examples.

A third interconnect layer 810 (referred to as Metal 3 or “M3”) (and additional interconnect layers, as desired) may be formed in succession on the second interconnect layer 808 according to similar techniques and configurations described in connection with the second interconnect layer 808 and/or the first interconnect layer 806. In some examples, the interconnect layers that are “higher up” in the metallization stack 819 in the IC device 800 (i.e., further away from the device layer 804) may be thicker.

The IC device 800 may include an example solder resist material 834 (e.g., polyimide or similar material) and one or more example conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to other external devices. For example, solder bonds may be formed on the one or more conductive contacts 836 to mechanically and/or electrically couple a chip including the IC device 800 with another component (e.g., a circuit board). The IC device 800 may include additional or alternate structures to route the electrical signals from the interconnect layers 806-810; for example, the conductive contacts 836 may include other analogous features (e.g., posts) that route the electrical signals to external components.

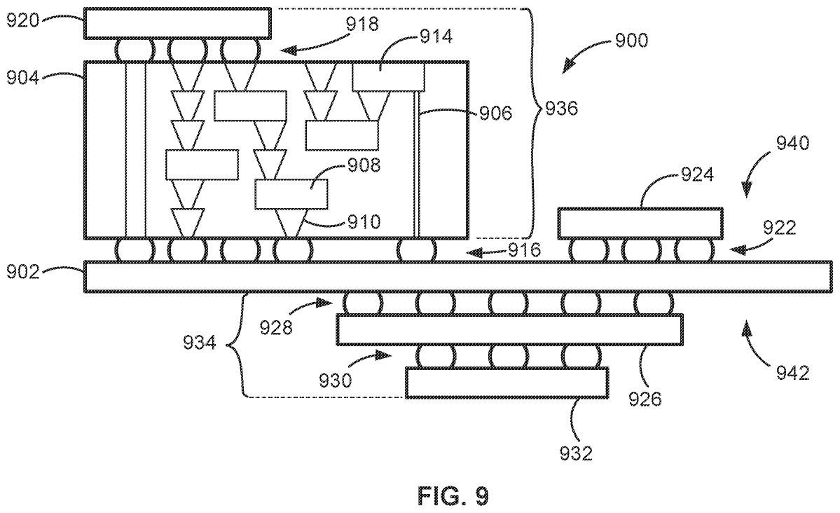

FIG. 9 is a cross-sectional side view of an example IC device assembly 900 that may include the IC package 100 disclosed herein. In some examples, the IC device assembly corresponds to the IC package 100. The IC device assembly 900 includes a number of components disposed on an example circuit board 902 (which may be, for example, a motherboard). The IC device assembly 900 includes components disposed on an example first face 940 of the circuit board 902 and an example opposing second face 942 of the circuit board 902. Any of the IC packages discussed herein with reference to the IC device assembly 900 may take the form of the example IC package 100.

In some examples, the circuit board 902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other examples, the circuit board 902 may be a non-PCB substrate. In some examples, the circuit board 902 may be, for example, the circuit board 102 of FIG. 1.

The IC device assembly 900 illustrated in FIG. 9 includes an example package-on-interposer structure 936 coupled to the first face 940 of the circuit board 902 by example coupling components 916. The coupling components 916 may electrically and mechanically couple the package-on-interposer structure 936 to the circuit board 902, and may include solder balls (as shown in FIG. 9), male and female portions of a socket, an adhesive, an underfill material, and/or any other suitable electrical, chemical, and/or mechanical coupling structure.

The package-on-interposer structure 936 may include an example IC package 920 coupled to an example interposer 904 by example coupling components 918. The coupling components 918 may take any suitable form for the application, such as the forms discussed above with reference to the coupling components 916. Although a single IC package 920 is shown in FIG. 9, multiple IC packages may be coupled to the interposer 904. Additionally or alternatively, in some examples, additional interposers may be coupled to the interposer 904. The interposer 904 may provide an intervening substrate used to bridge the circuit board 902 and the IC package 920. The IC package 920 may be or include, for example, a die (the die 702 of FIG. 7), an IC device (e.g., the IC device 800 of FIG. 8), and/or any other suitable component(s). Generally, the interposer 904 may spread a connection to a wider pitch or reroute a connection to a different connection. For example, the interposer 904 may couple the IC package 920 (e.g., a die) to a set of BGA conductive contacts of the coupling components 916 for coupling to the circuit board 902. In the example illustrated in FIG. 9, the IC package 920 and the circuit board 902 are attached to opposing sides of the interposer 904. In other examples, the IC package 920 and the circuit board 902 may be attached to a same side of the interposer 904. In some examples, three or more components may be interconnected by way of the interposer 904.

In some examples, the interposer 904 may be formed as a PCB, including multiple metal layers separated from one another by layers of dielectric material and interconnected by electrically conductive vias. In some examples, the interposer 904 may be formed of an epoxy resin, a fiberglass-reinforced epoxy resin, an epoxy resin with inorganic fillers, a ceramic material, or a polymer material such as polyimide. In some examples, the interposer 904 may be formed of alternate rigid or flexible materials that may include the same materials described above for use in a semiconductor substrate, such as silicon, germanium, and other group III-V and group IV materials. The interposer 904 may include example metal interconnects 908 and example vias 910, including but not limited to example through-silicon vias (TSVs) 906. The interposer 904 may further include example embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an example IC package 924 coupled to the first face 940 of the circuit board 902 by example coupling components 922. The coupling components 922 may take the form of any of the examples discussed above with reference to the coupling components 916, and the IC package 924 may take the form of any of the examples discussed above with reference to the IC package 920.

The IC device assembly 900 illustrated in FIG. 9 includes an example package-on-package structure 934 coupled to the second face 942 of the circuit board 902 by coupling components 928. The package-on-package structure 934 may include a first example IC package 926 and a second example IC package 932 coupled together by example coupling components 930 such that the first IC package 926 is disposed between the circuit board 902 and the second IC package 932. The coupling components 928, 930 may take the form of any of the examples of the coupling components 916 discussed above, and the IC packages 926, 932 may take the form of any of the examples of the IC package 920 discussed above.

FIG. 10 is a block diagram of an example electrical device 1000 that may include one or more of the example IC package 100. For example, any suitable ones of the components of the electrical device 1000 may include one or more of the device assemblies 900, IC devices 800, or dies 702 disclosed herein, and may be arranged in the example IC package 100. A number of components are illustrated in FIG. 10 as included in the electrical device 1000, but any one or more of these components may be omitted or duplicated, as suitable for the application. In some examples, some or all of the components included in the electrical device 1000 may be attached to one or more motherboards. In some examples, some or all of these components are fabricated onto a single system-on-a-chip (SoC) die.

Additionally, in some examples, the electrical device 1000 may not include one or more of the components illustrated in FIG. 10, but the electrical device 1000 may include interface circuitry for coupling to the one or more components. For example, the electrical device 1000 may not include an example display 1006, but may include display interface circuitry (e.g., a connector and driver circuitry) to which the display 1006 may be coupled. In some examples, the electrical device 1000 may not include an example audio input device 1018 (e.g., microphone) or an example audio output device 1008 (e.g., a speaker, a headset, earbuds, etc.), but may include audio input or output device interface circuitry (e.g., connectors and supporting circuitry) to which the audio input device 1018 or the audio output device 1008 may be coupled.

The electrical device 1000 may include example programmable or processor circuitry 1002 (e.g., one or more processing devices). The processor circuitry 1002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1000 may include an example memory 1004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1004 may include memory that shares a die with the processor circuitry 1002. This memory may be used as cache memory and may include embedded dynamic random access memory (eDRAM) or spin transfer torque magnetic random access memory (STT-MRAM).

In some examples, the electrical device 1000 may include an example communication chip 1012 (e.g., one or more communication chips). For example, the communication chip 1012 may be configured for managing wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other examples. The electrical device 1000 may include an example antenna 1022 to facilitate wireless communications and/or to receive other wireless communications (such as AM or FM radio transmissions).

In some examples, the communication chip 1012 may manage wired communications, such as electrical, optical, or any other suitable communication protocols (e.g., the Ethernet). As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some examples, a first communication chip 1012 may be dedicated to wireless communications, and a second communication chip 1012 may be dedicated to wired communications.

The electrical device 1000 may include example battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include the display 1006 (or corresponding interface circuitry, as discussed above). The display 1006 may include any visual indicators, such as a heads-up display, a computer monitor, a projector, a touchscreen display, a liquid crystal display (LCD), a light-emitting diode display, or a flat panel display.

The electrical device 1000 may include the audio output device 1008 (or corresponding interface circuitry, as discussed above). The audio output device 1008 may include any device that generates an audible indicator, such as speakers, headsets, or earbuds.

The electrical device 1000 may include the audio input device 1018 (or corresponding interface circuitry, as discussed above). The audio input device 1018 may include any device that generates a signal representative of a sound, such as microphones, microphone arrays, or digital instruments (e.g., instruments having a musical instrument digital interface (MIDI) output).

The electrical device 1000 may include example GPS circuitry 1016. The GPS circuitry 1016 may be in communication with a satellite-based system and may receive a location of the electrical device 1000, as known in the art.

The electrical device 1000 may include any other example output device 1010 (or corresponding interface circuitry, as discussed above). Examples of the other output device 1010 may include an audio codec, a video codec, a printer, a wired or wireless transmitter for providing information to other devices, and/or an additional storage device.

The electrical device 1000 may include any other example input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1000 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1000 may be any other electronic device that processes data.

From the foregoing, it will be appreciated that example systems, apparatus, articles of manufacture, and methods have been disclosed that utilize a non-conductive material to cover interconnects between semiconductor dies and package substrates in which the dies are embedded to serve as interconnect bridges. In disclosed examples, the non-conductive material inhibits residual material from spreading or leaking into adjacent regions in response to mass reflow techniques. As such, disclosed examples enable sufficient mechanical and electrical coupling between semiconductor dies and package substrates. Further, examples disclosed herein can bypass previous, conventional deflux techniques to remove such residual material.
Example 1 includes a package substrate comprising a dielectric layer including a cavity, a first contact pad positioned in the cavity, a first semiconductor die including a second contact pad and a third contact pad, the second contact pad positioned on a first surface of the first semiconductor die, the third contact pad positioned on a second surface of the first semiconductor die, the second surface opposite the first surface, the second contact pad conductively coupled to the first contact pad, and a non-conductive material surrounding the first contact pad and the second contact pad.
Example 2 includes the package substrate of example 1, further including a fourth contact pad positioned on the second surface of the first semiconductor die, the third contact pad to be conductively coupled to a second semiconductor die, the fourth contact pad to be conductively coupled to a third semiconductor die, the second and third semiconductor dies conductively coupled through the third and fourth contact pads.
Example 3 includes the package substrate of example 1, further including a build-up region adjacent to the first semiconductor die, the build-up region including the dielectric layer, and a via extending through the build-up region, the via and the first semiconductor die conductively coupled through the first and second contact pads.
Example 4 includes the package substrate of example 1, further including a mold underfill positioned in the cavity, the mold underfill surrounding the non-conductive material.
Example 5 includes the package substrate of example 4, wherein the mold underfill surrounds the first semiconductor die.
Example 6 includes the package substrate of example 4, further including a build-up region adjacent to the first semiconductor die, the build-up region including the dielectric layer, wherein the mold underfill covers a surface of the build-up region, the surface of the build-up region facing in a first direction, the first surface of the first semiconductor die facing in a second direction opposite the first direction.
Example 7 includes the package substrate of example 1, wherein the first semiconductor die is spaced apart from a wall of the cavity.
Example 8 includes the package substrate of example 7, wherein the non-conductive material is between the first semiconductor die and the wall of the cavity.
Example 9 includes the package substrate of example 7, further including a mold underfill, the mold underfill between the first semiconductor die and the wall of the cavity.
Example 10 includes an integrated circuit (IC) package comprising a package substrate supporting a semiconductor die, an interconnect bridge positioned within the package substrate, the interconnect bridge conductively coupled to the semiconductor die, and a non-conductive coating between the interconnect bridge and a surface of the package substrate, the surface of the package substrate including a contact pad, the interconnect bridge conductively coupled to the package substrate via the contact pad.
Example 11 includes the IC package of example 10, wherein the surface is a first surface of the package substrate, further including a via extending from the contact pad towards a second surface of the package substrate, the second surface of the package substrate facing away from the first surface.
Example 12 includes the IC package of example 10, wherein a first surface of the interconnect bridge faces the surface of the package substrate, the non-conductive coating to at least partially cover a second surface of the interconnect bridge, the second surface different than the first surface.
Example 13 includes the IC package of example 10, wherein the surface of the package substrate is a first surface, the first surface recessed relative to a second surface of the package substrate, the semiconductor die supported on the second surface.
Example 14 includes the IC package of example 10, further including a mold material in contact with the interconnect bridge and the surface of the package substrate.
Example 15 includes the IC package of example 14, wherein the mold material at least partially surrounds the contact pad.
Example 16 includes the IC package of example 14, wherein a first surface of the interconnect bridge faces the surface of the package substrate, the mold material to cover the first surface and a second surface of the interconnect bridge, the second surface different from the first surface.
Example 17 includes the IC package of example 14, wherein the mold material is positioned between the interconnect bridge and the surface of the package substrate.
Example 18 includes a package substrate comprising a recessed surface, a first contact pad positioned on the recessed surface, a first semiconductor die including a second contact pad, a third contact pad, and a fourth contact pad, the second contact pad positioned on a first side of the first semiconductor die, the third contact pad and the fourth contact pad positioned on a second side of the first semiconductor die, the second side opposite the first side, the second contact pad mechanically coupled to the first contact pad, the third contact pad to be mechanically coupled to a second semiconductor die, the fourth contact pad to be mechanically coupled to a third semiconductor die, and a non-conductive material to encapsulate the first contact pad and the second contact pad.
Example 19 includes the package substrate of example 18, wherein the second semiconductor die is conductively coupled to the third semiconductor die through the third and fourth contact pads.
Example 20 includes the package substrate of example 18, further including a mold underfill positioned in the cavity, the mold underfill surrounding the non-conductive material.
Example 21 includes a method comprising providing a package substrate including a dielectric layer having a cavity, the dielectric layer having a first contact pad positioned in the cavity, depositing a non-conductive material in the cavity, and adding an interconnect bridge to the cavity, the interconnect bridge including a second contact pad, the second contact pad coupled to the first contact pad, the non-conductive material surrounding the first and second contact pads.
Example 22 includes the method of example 21, further including depositing the non-conductive material to at least partially cover the second contact pad.
Example 23 includes the method of example 21, further including depositing a mold underfill in the cavity, the mold underfill to surround the non-conductive material and the first and second contact pads.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate comprising:
a dielectric layer including a cavity;
a first contact pad positioned in the cavity;
a first semiconductor die including a second contact pad and a third contact pad, the second contact pad positioned on a first surface of the first semiconductor die, the third contact pad positioned on a second surface of the first semiconductor die, the second surface opposite the first surface, the second contact pad conductively coupled to the first contact pad; and
a non-conductive material surrounding the first contact pad and the second contact pad.

2. The package substrate of claim 1, further including a fourth contact pad positioned on the second surface of the first semiconductor die, the third contact pad to be conductively coupled to a second semiconductor die, the fourth contact pad to be conductively coupled to a third semiconductor die, the second and third semiconductor dies conductively coupled through the third and fourth contact pads.

3. The package substrate of claim 1, further including:
a build-up region adjacent to the first semiconductor die, the build-up region including the dielectric layer; and
a via extending through the build-up region, the via and the first semiconductor die conductively coupled through the first and second contact pads.

4. The package substrate of claim 1, further including a mold underfill positioned in the cavity, the mold underfill surrounding the non-conductive material.

5. The package substrate of claim 4, wherein the mold underfill surrounds the first semiconductor die.

6. The package substrate of claim 4, further including a build-up region adjacent to the first semiconductor die, the build-up region including the dielectric layer, wherein the mold underfill covers a surface of the build-up region, the surface of the build-up region facing in a first direction, the first surface of the first semiconductor die facing in a second direction opposite the first direction.

7. The package substrate of claim 1, wherein the first semiconductor die is spaced apart from a wall of the cavity.

8. The package substrate of claim 7, wherein the non-conductive material is between the first semiconductor die and the wall of the cavity.

9. The package substrate of claim 7, further including a mold underfill, the mold underfill between the first semiconductor die and the wall of the cavity.

10. An integrated circuit (IC) package comprising:
a package substrate supporting a semiconductor die;
an interconnect bridge positioned within the package substrate, the interconnect bridge conductively coupled to the semiconductor die; and
a non-conductive coating between the interconnect bridge and a surface of the package substrate, the surface of the package substrate including a contact pad, the interconnect bridge conductively coupled to the package substrate via the contact pad.

11. The IC package of claim 10, wherein the surface is a first surface of the package substrate, further including a via extending from the contact pad towards a second surface of the package substrate, the second surface of the package substrate facing away from the first surface.

12. The IC package of claim 10, wherein a first surface of the interconnect bridge faces the surface of the package substrate, the non-conductive coating to at least partially cover a second surface of the interconnect bridge, the second surface different than the first surface.

13. The IC package of claim 10, wherein the surface of the package substrate is a first surface, the first surface recessed relative to a second surface of the package substrate, the semiconductor die supported on the second surface.

14. The IC package of claim 10, further including a mold material in contact with the interconnect bridge and the surface of the package substrate.

15. The IC package of claim 14, wherein the mold material at least partially surrounds the contact pad.

16. The IC package of claim 14, wherein a first surface of the interconnect bridge faces the surface of the package substrate, the mold material to cover the first surface and a second surface of the interconnect bridge, the second surface different from the first surface.

17. The IC package of claim 14, wherein the mold material is positioned between the interconnect bridge and the surface of the package substrate.

18. A package substrate comprising:
a recessed surface;
a first contact pad positioned on the recessed surface;
a first semiconductor die including a second contact pad, a third contact pad, and a fourth contact pad, the second contact pad positioned on a first side of the first semiconductor die, the third contact pad and the fourth contact pad positioned on a second side of the first semiconductor die, the second side opposite the first side, the second contact pad mechanically coupled to the first contact pad, the third contact pad to be mechanically coupled to a second semiconductor die, the fourth contact pad to be mechanically coupled to a third semiconductor die; and
a non-conductive material to encapsulate the first contact pad and the second contact pad.

19. The package substrate of claim 18, wherein the second semiconductor die is conductively coupled to the third semiconductor die through the third and fourth contact pads.

20. The package substrate of claim 18, further including a mold underfill positioned in the cavity, the mold underfill surrounding the non-conductive material.
